(19) United States
(12) Patent Application Publication
(10) Pub. No.: US 2026/0012137 A1
(43) Pub. Date: Jan. 8, 2026

(54) POWER AMPLIFYING CIRCUIT AND CONTROL METHOD OF POWER AMPLIFYING CIRCUIT

(71) Applicant: Murata Manufacturing Co., Ltd., Nagaokakyo-shi (JP)

(72) Inventors: Kenji TAHARA, Nagaokakyo-shi (JP); Kae Yamamoto, Nagaokakyo-shi (JP)

(21) Appl. No.: 19/328,298

(22) Filed: Sep. 15, 2025

Related U.S. Application Data
(63) Continuation of application No. PCT/JP2024/005702, filed on Feb. 19, 2024.

(30) Foreign Application Priority Data
Mar. 22, 2023 (JP) 2023-045495

(51) Int. Cl. H03F 1/02; H03F 3/60

(52) U.S. Cl. CPC H03F 1/0288; H03F 1/0222; H03F 3/602; H03F 2200/102; H03F 2200/451

(57) ABSTRACT

A power amplifying circuit includes a splitter connected to an input terminal, a combiner connected to an output terminal, a carrier amplifier group, a peaking amplifier group, a phase shifter, and a bias control circuit. The splitter splits an input signal from the input terminal for two paths. The carrier amplifier group is connected to one of the two paths of the splitter. The phase shifter is connected between the carrier amplifier group and the combiner. The peaking amplifier group is connected between another of the two paths of the splitter and the combiner. The bias control circuit supplies bias signals to each amplifier group. At least one of the amplifier groups includes a plurality of amplifiers. The control circuit changes a quantity of amplifiers to use in each amplifier group by adjusting a level of the bias signal being supplied to each amplifier.

### CROSS REFERENCE TO RELATED APPLICATION

This is a continuation of International Application No. PCT/JP2024/005702 filed on Feb. 19, 2024 which claims priority from Japanese Patent Application No. 2023-045495 filed on Mar. 22, 2023. The contents of these applications are incorporated herein by reference in their entireties.

### BACKGROUND OF THE DISCLOSURE

### Field of the Disclosure

The present disclosure relates to power amplifying circuits and control methods of power amplifying circuits, and more particularly to techniques for improving the efficiency of power amplifiers.

### Description of the Related Art

In wireless communication systems, power amplifiers are used for amplifying high frequency signals that are transmitted via antennas. Generally, in mobile communication devices that are typified by mobile phones and smartphones, batteries are used as power supplies. With such mobile devices, it is desirable that a long battery life be realized by reducing power consumption in order to achieve a stable operation for an extended period of time.

U.S. Patent Application Publication No. 2021/0099137 discloses a configuration of an envelope tracking system for a power amplifier for a radio frequency (RF) electronic device, which improves the efficiency of the power amplifier by variably setting the voltage level of supply voltage to the power amplifier on the basis of the power level of a RF signal.

### BRIEF SUMMARY OF THE DISCLOSURE

In recent years, for realization of a high-capacity high-speed network, the frequency utilization efficiency is being improved using multilevel modulation signals, and the communication speed is being increased by expanding channel band widths. Because of this, a further reduction in power consumption is desired, and this necessitates a further increase in the efficiency of the power amplifier.

In order to improve the efficiency of the power amplifier, it is necessary to set an appropriate supply voltage that is associated with the power level of the input signal. As described above, in U.S. Patent Application Publication No. 2021/0099137, the supply voltage to the power amplifier is changed according to the power level of the input signal. However, in a case where the amplitude variation of the input signal is large or in a case where the frequency band width of the input signal is wide, the adjustment of the supply voltage sometimes cannot follow variation of the input signal.

Further, in the case where the multilevel modulation control is used, the back-off amount, which is defined by the ratio between a peak power and an average power, tends to increase as the quantity of symbols in the multilevel modulation increases. However, with the configuration disclosed in U.S. Patent Application Publication No. 2021/0099137, the back-off amount cannot be adjusted. Thus, in the case where the back-off amount varies as the quantity of symbols changes, the efficiency of the power amplifier suited for this back-off amount sometimes cannot be achieved.

The present disclosure is made to resolve the issues described above, and a possible benefit thereof is to reduce the decrease in efficiency relating to the variation in the back-off amount in a power amplifier for use in a radio frequency communication device.

A power amplifying circuit according to one aspect of the present disclosure includes an input terminal, an output terminal, a splitter connected to the input terminal, a combiner connected to the output terminal, a first amplifier group, a second amplifier group, a first phase shifter, and a control circuit. The splitter splits an input signal from the input terminal for two paths. The first amplifier group is connected to one of the two paths of the splitter. The first phase shifter is connected between the first amplifier group and the combiner. The second amplifier group is connected between another of the two paths of the splitter and the combiner. The control circuit supplies bias signals to the first amplifier group and the second amplifier group. At least one of the first amplifier group and the second amplifier group includes a plurality of amplifiers. The control circuit changes the quantity of amplifiers to use in each of the first amplifier group and the second amplifier group by adjusting the level of the bias signal being supplied to each amplifier.

A control method of a power amplifying circuit according to another aspect of the present disclosure relates to a control method for a power amplifying circuit including an input terminal, an output terminal, a first amplifier group, and a second amplifier group, the first amplifier group and the second amplifier group being connected in parallel between the input terminal and the output terminal. At least one of the first amplifier group and the second amplifier group includes a plurality of amplifiers. The control method includes: (i) a step of acquiring a magnitude of an input signal; (ii) a step of selecting a back-off amount that is associated with the magnitude of the input signal acquired; and (iii) a step of setting a quantity of amplifiers to use in each of the first amplifier group and the second amplifier group on a basis of the input signal and the back-off amount.

A control method of a power amplifying circuit according to still another aspect of the present disclosure relates to a control method for a power amplifying circuit including an input terminal, an output terminal, a first amplifier group, and a second amplifier group, the first amplifier group and the second amplifier group being connected in parallel between the input terminal and the output terminal. At least one of the first amplifier group and the second amplifier group includes a plurality of amplifiers. The control method includes: (i) a step of acquiring a magnitude of an input signal; (ii) a step of acquiring a magnitude of an output signal; and (iii) a step of changing a quantity of amplifiers to use in each of the first amplifier group and the second amplifier group on a basis of the input signal and the output signal.

The power amplifying circuit according to the present disclosure, which is a Doherty amplifier, includes the first amplifier group (carrier amplifier) and the second amplifier group (peaking amplifier), at least one of these two amplifier groups includes a plurality of amplifiers. Furthermore, the quantity of amplifiers to use in each amplifier group is changed by adjusting the level of the bias signal being supplied to each amplifier. Because of this, even when the back-off amount varies, by changing the quantity of the carrier amplifiers and/or the quantity of the peaking amplifiers to use, it becomes possible to adjust the output characteristic in such a way that the adjusted output characteristic is associated with the back-off amount. Therefore, in the power amplifying circuit for use in the wireless communication device, it becomes possible to reduce the decrease in efficiency relating to the variation in the back-off amount.

### BRIEF DESCRIPTION OF THE SEVERAL VIEWS OF THE DRAWINGS

FIG. 1 is a schematic configuration diagram of a communication device in which a power amplifying circuit according to Embodiment 1 is employed.

FIG. 2 is a diagram illustrating a detailed configuration of the power amplifying circuit in FIG. 1.

FIG. 3 is a diagram to illustrate envelope tracking modes of a power supply circuit.

FIG. 4 is a diagram to illustrate the working of a Doherty amplifier.

FIG. 5 is a diagram illustrating examples of the efficiency in relation to the output power in respective envelope tracking modes.

FIG. 6 is a diagram illustrating one example of the efficiency in relation to the output power for the Doherty amplifier.

FIG. 7 is a diagram to illustrate the relationship between the modulation scheme and the back-off amount.

FIG. 8 is a first example of the working of the power amplifying circuit of Embodiment 1.

FIG. 9 is a second example of the working of the power amplifying circuit of Embodiment 1.

FIG. 10 is a third example of the working of the power amplifying circuit of Embodiment 1.

FIG. 11 is a fourth example of the working of the power amplifying circuit of Embodiment 1.

FIG. 12 is a diagram illustrating a first example of the efficiency in relation to the output power in a case where the power amplifying circuit of Embodiment 1 is used.

FIG. 13 is a diagram illustrating a second example of the efficiency in relation to the output power in a case where the power amplifying circuit of Embodiment 1 is used.

FIG. 14 is a flowchart illustrating control to be performed in the communication device of Embodiment 1.

FIG. 15 is a schematic configuration diagram of a communication device in which a power amplifying circuit according to Embodiment 2 is employed.

FIG. 16 is a diagram to illustrate an effect of load variation on the gain of the power amplifying circuit.

FIG. 17 is a diagram to illustrate an effect of load variation on the efficiency.

FIG. 18 is a diagram to illustrate an effect of load variation on the distortion.

FIG. 19 is a flowchart illustrating control to be performed in the communication device of Embodiment 2.

### DETAILED DESCRIPTION OF THE DISCLOSURE

Hereinafter, embodiments of the present disclosure will be described in detail with reference to the drawings. Note that the same reference characters are assigned to the same or corresponding parts of the drawings, and the descriptions thereof will not be repeated.

### Embodiment 1

### (Configuration of Communication Device and Power Amplifying Circuit)

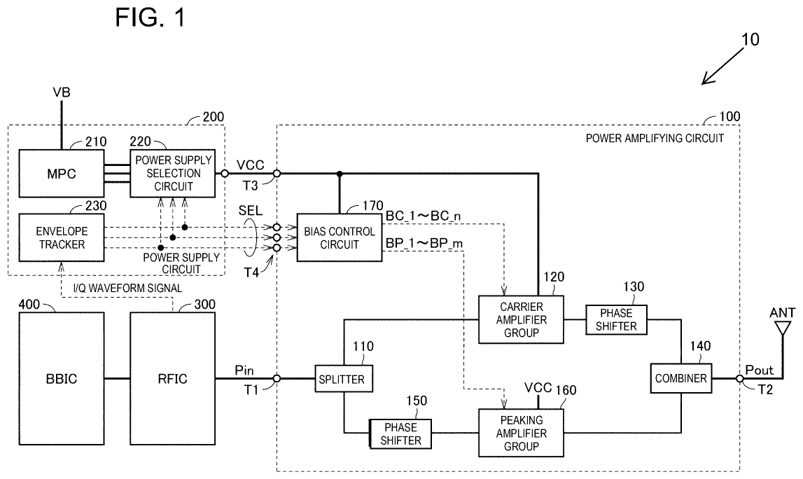

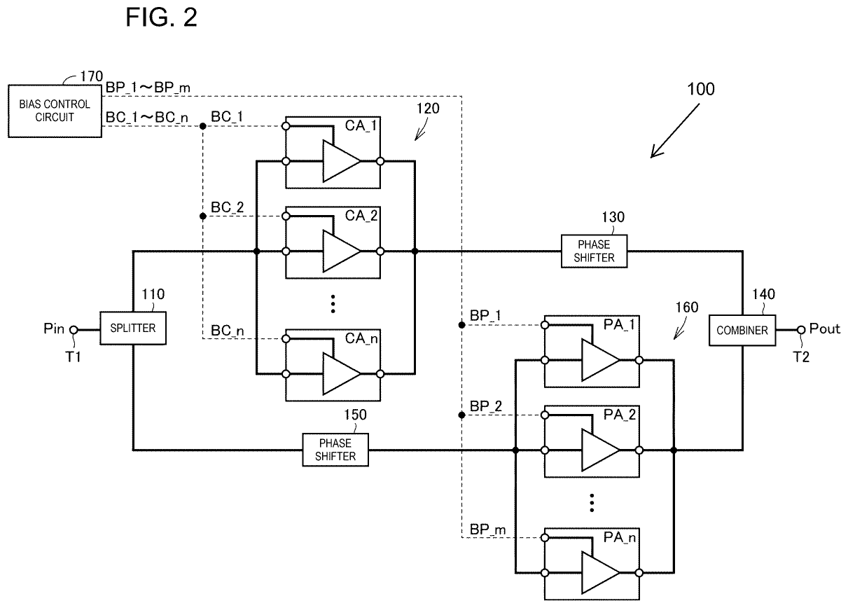

Referring to FIG. 1 and FIG. 2, a configuration of a communication device 10 according to Embodiment 1 is described. FIG. 1 is a schematic configuration diagram of the communication device 10 in which a power amplifying circuit 100 according to Embodiment 1 is employed. FIG. 2 is a diagram illustrating a detailed configuration of the power amplifying circuit 100 in FIG. 1. The communication device 10 is, for example, a mobile terminal such as a mobile phone, a smartphone, a tablet, or the like, a personal computer with communication capability, or the like.

Referring to FIG. 1, the communication device 10 includes, in addition to the power amplifying circuit 100, an antenna ANT, a power supply circuit 200, a RFIC (Radio Frequency Integrated Circuit) 300, and a BBIC (Baseband Integrated Circuit) 400 that constitutes a baseband signal processing circuit. The communication device 10 up-converts an intermediate frequency (IF) signal transmitted from the BBIC 400 into a high frequency (radio frequency: RF) signal using the RFIC 300, amplifies this high frequency signal using the power amplifying circuit 100, and radiates the amplified high frequency signal from the antenna ANT. Further, although it is not illustrated in FIG. 1, the communication device 10 down-converts a high frequency signal received by the antenna ANT using the RFIC 300 and processes the down-converted signal using the BBIC 400.

The power amplifying circuit 100 includes an input terminal T1, an output terminal T2, a power supply terminal T3, a plurality of control terminals T4, a splitter 110, a carrier amplifier group 120, phase shifters 130 and 150, a combiner 140, a peaking amplifier group 160, and a bias control circuit 170. In the outline, the carrier amplifier group 120 and the peaking amplifier group 160 are connected in parallel between the input terminal T1 and the output terminal T2 in the power amplifying circuit 100. That is to say, the power amplifying circuit 100 is a so-called “Doherty amplifier”.

The power supply terminal T3 receives a power supply voltage VCC supplied from the power supply circuit 200. The power supply voltage VCC received at the power supply terminal T3 is supplied to the carrier amplifier group 120, the peaking amplifier group 160, and the bias control circuit 170 as the power supply for driving.

The control terminals T4 receive selection signals SEL from the power supply circuit 200 and transmit these signals to the bias control circuit 170. The bias control circuit 170 generates bias signals for all the amplifiers included in the carrier amplifier group 120 and the peaking amplifier group 160 on the basis of the selection signals SEL received via the control terminals T4. The bias control circuit 170 adjusts the level of voltage or current of the bias signal. In the following description, examples are described for the case where the voltage signal is used as the bias signal.

The splitter 110 splits an input signal Pin from the RFIC 300 received at the input terminal T1 for two signal paths (first path and second path). The carrier amplifier group 120 is connected to the first path of the splitter 110. Further, the peaking amplifier group 160 is connected to the second path of the splitter 110 via the phase shifter 150.

The output of the carrier amplifier group 120 is connected to the combiner 140 via the phase shifter 130. Further, the output of the peaking amplifier group 160 is connected to the combiner 140. The combiner 140 combines the signals amplified in the carrier amplifier group 120 and the peaking amplifier group 160 and outputs an output signal Pout. The output signal Pout is radiated from the antenna ANT connected to the output terminal T2.

Note that in FIG. 1, the example is illustrated in which the output terminal T2 of the power amplifying circuit 100 is directly connected to the antenna ANT. Alternatively, a filter device and/or a band selection switch (both are not illustrated) may be provided between the output terminal T2 and the antenna ANT.

The carrier amplifier group 120 includes at least one amplifier. In the example of FIG. 2, the carrier amplifier group 120 includes n amplifiers CA_1 to CA_n (hereinafter, also collectively referred to as “amplifiers CA”) (n≤1), which are connected in parallel. As the amplifiers CA included in the carrier amplifier group 120, Class A amplifiers or Class AB amplifiers, which have relatively small distortions, are used. Note that in Embodiment 1, the example is described for the case where all the amplifiers CA are amplifiers having the same specification. Alternatively, the specification of some of those amplifiers may differ from the specification of the other amplifiers.

The amplifiers CA amplify the input signal supplied from the splitter 110 using the power supply voltage VCC supplied from the power supply circuit 200. Bias voltages BC_1 to BC_n (hereinafter, also collectively referred to as “bias voltages BC”) from the bias control circuit 170 are supplied to the amplifiers CA_1 to CA_n, respectively. Changing the magnitude of the bias voltage BC enables the selection of the amplifier to use from the amplifiers CA_1 to CA_n.

The phase shifter 130 adjusts the phase of the signal amplified by the carrier amplifier group 120. The phase shifter 130 is, for example, a quarter-wavelength transmission line and capable of delaying the phase of the signal amplified by the carrier amplifier group 120 by 90 degrees. Further, the phase shifter 130 is capable of rotating the load impedance 180 degrees on the Smith chart. That is to say, the phase shifter 130 functions as an impedance inverter.

The phase shifter 150 is capable of adjusting the phase between the signal of the first path and the signal of the second path, which have been split by the splitter 110. For example, the phase shifter 150 delays the phase of the signal split for the second path by 90 degrees relative to the phase of the signal split for the first path and supplies the delayed signal to the peaking amplifier group 160. Note that the amount of the phase adjustment in the phase shifter 150 is not limited to the above and may be appropriately selected on the basis of an internal configuration such as, for example, the lengths of the lines from the splitter 110 to the respective amplifier groups or the like.

The peaking amplifier group 160 includes at least one amplifier. In the example of FIG. 2, the peaking amplifier group 160 includes m amplifiers PA_1 to PA_m (hereinafter, also collectively referred to as “amplifiers PA”) (m≥1), which are connected in parallel. As the amplifiers PA included in the peaking amplifier group 160, Class C amplifiers are used. By using the Class C amplifier, the amplifier PA stops its amplification operation when the voltage level of the input signal becomes less than or equal to a predetermined value. Note that in Embodiment 1, the example is described for the case where all the amplifiers PA are amplifiers having the same specification. Alternatively, some of the amplifiers may have specifications that differ from those of the other amplifiers.

The amplifiers PA amplify the input signal supplied from the splitter 110 using the power supply voltage VCC supplied from the power supply circuit 200. Bias voltages BP_1 to BP_m (hereinafter, also collectively referred to as “bias voltages BP”) from the bias control circuit 170 are supplied to the amplifiers PA_1 to PA_m, respectively. Changing the magnitude of the bias voltage BP enables the selection of the amplifier to use from the amplifiers PA_1 to PA_m.

Note that in this Embodiment 1, at least one of the carrier amplifier group 120 and the peaking amplifier group 160 includes a plurality of amplifiers.

The power supply circuit 200 is one example of a so-called digital tracker and capable of supplying the power supply voltage VCC to the power amplifying circuit 100 at a plurality of different voltage levels. The power supply circuit 200 includes a multilevel power converter (MPC) 210, a power supply selection circuit 220, and an envelope tracker 230.

The MPC 210 includes a plurality of DC/DC converters. The MPC 210 converts a battery voltage VB supplied from an external battery into a plurality of different voltage levels and supplies the converted voltages to the power supply selection circuit 220.

The envelope tracker 230 receives an I/Q waveform signal of the input signal Pin from the RFIC 300 and tracks the envelope of the input signal Pin using a digital envelope tracking (ET) mode. The envelope tracker 230 generates a plurality of selection signals SEL that are associated with voltage levels of the envelope of the input signal Pin and outputs the plurality of selection signals SEL to the power supply selection circuit 220 and the bias control circuit 170 of the power amplifying circuit 100.

The power supply selection circuit 220 selects, from the plurality of voltage levels supplied from the MPC 210, the voltage that is associated with the selection signal SEL sent from the envelope tracker 230, and supplies the selected voltage to the carrier amplifier group 120, the peaking amplifier group 160, and the bias control circuit 170 of the power amplifying circuit 100 as the power supply voltage VCC.

### (Description of Envelope Tracking Mode)

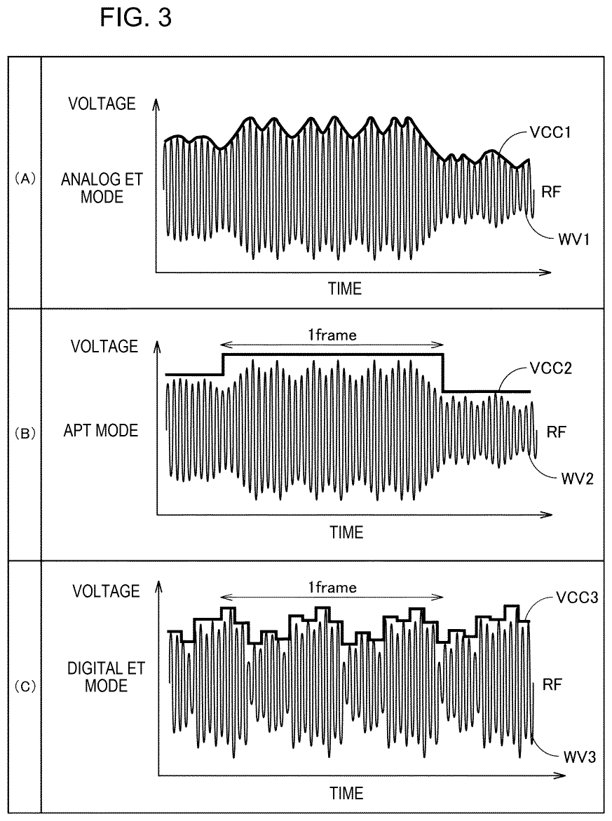

Next, referring to FIG. 3, tracking modes for adjusting the power supply voltage level are described. In general, the tracking modes are classified into the envelope tracking mode and the average power tracking (APT) mode. Further, the envelope tracking mode is classified into the “digital ET mode” and the “analog envelope tracking mode (analog ET mode)”. The envelope tracking mode is a mode in which the level of the power supply voltage is set on the basis of an envelope signal that indicates the envelope of the input signal. On the other hand, the APT mode is a mode in which the level of the power supply voltage is set on the basis of, not the envelope signal, but the average output power in a predetermined period.

In FIG. 3, the upper part (A) illustrates a graph illustrating one example of a change in the power supply voltage in the analog ET mode. Further, the middle part (B) and the lower part (C) illustrate graphs illustrating examples of changes in the power supply voltage in the APT mode and the digital ET mode, respectively. In each graph, the horizontal axis indicates the time, and the vertical axis indicates the voltage. Thick solid lines VCCI to VCC3 indicate the power supply voltages in the respective modes, and thin solid lines WV1 to WV3 indicate the input signals Pin that are high frequency signals after the modulation.

In the analog ET mode (upper part (A)), the power supply voltage is set to change continuously so that the power supply voltage follows the envelope of the input signal Pin. The waveform of the power supply voltage in the analog ET mode is not a digital waveform but an analog waveform.

It could be said that the analog ET mode is the most efficient tracking because the power supply voltage associated with the amplitude variation of the input signal Pin is constantly supplied. However, it is necessary to continuously change the power supply voltage. Thus, when the amplitude variation of the input signal is large, or when the modulation band width is wide, the power supply voltage cannot follow the envelope of the high frequency signal after the modulation in some cases.

Next, in the case of the APT mode in the middle part (B), the power supply voltage of a different voltage level is set for each predetermined single frame unit. The power supply voltage has a digital waveform and forms a rectangular wave. Here, the frame means a unit that constitutes a high frequency signal after the modulation. In one example, the length of the frame is 10 ms.

Specifically, in the APT mode, the voltage level of the power supply voltage is determined on the basis of the average output power rather than the envelope signal. In this case, it is not necessary to follow the input signal Pin and quickly change the power supply voltage. However, in each frame, a voltage larger than the input signal Pin is set, and thus, there is room for improvement from the viewpoint of power saving and efficiency.

In the digital ET mode (lower part (C)), the power supply voltages at a plurality of different voltage levels are set within a single frame. The power supply voltage has a digital waveform and forms a rectangular wave. Specifically, in the digital ET mode, on the basis of the envelope signal, the voltage level associated with the voltage of the input signal Pin in a target period in the frame is selected from the plurality of different voltage levels. At this time, the voltage level is selected so as to track the envelope of the carrier wave that has been modulated on the basis of transmission information. More specifically, referring to the ranges of the envelope values that are respectively associated with the plurality of different voltage levels, the voltage level associated with the envelope value of each symbol is selected.

Here, the envelope signal is a signal that indicates the envelope value of the input signal Pin. In the case where (I, Q) is a constellation point, the envelope value is represented as a square root of (I²+Q²), for example. The constellation point is a point representing a modulated signal subjected to digital modulation on the constellation. For example, (I, Q) is determined by the BBIC 400 on the basis of the transmission information.

As described above, in the digital ET mode, by supplying the voltage level selected from the plurality of different voltage levels, it becomes possible to perform a relatively fast control that follows the envelope of the input signal Pin.

### (Description of Doherty Amplifier)

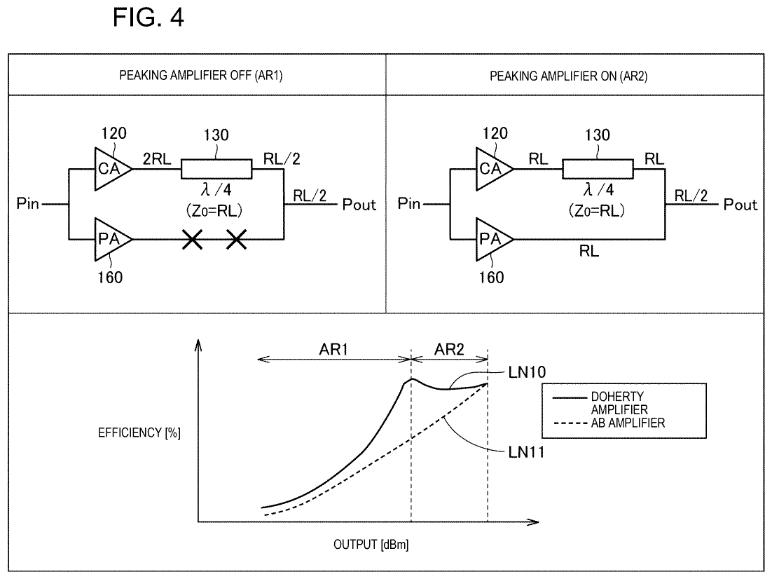

Next, an outline of a Doherty amplifier is described. FIG. 4 is a diagram to illustrate the working of a Doherty amplifier.

In the outline, as in the case of the power amplifying circuit 100 of Embodiment 1 illustrated in FIG. 1 and FIG. 2, the Doherty amplifier has a configuration in which the carrier amplifier and the peaking amplifier are connected in parallel to each other between the input terminal and the output terminal and the phase shifter that functions as an impedance inverter is arranged between the carrier amplifier and the combiner. Furthermore, when the output power is small, the carrier amplifier operates, and when the output power exceeds a predetermined value, both the carrier amplifier and the peaking amplifier operate.

In FIG. 4, the upper part illustrates the states of the circuit and the load impedance at a time when the peaking amplifier is in operation (right diagram) and at a time when the peaking amplifier is not in operation (left diagram), and the lower part illustrates the relationship between the output power and the efficiency of the Doherty amplifier in comparison with the case of the Class AB amplifier. In the lower part, a solid line LN10 indicates the efficiency for the case of the Doherty amplifier, and a dashed line LN11 indicates the efficiency for the case of the Class AB amplifier.

When both the carrier amplifier and the peaking amplifier are in operation (right diagram in the upper part), the load impedance seen from each one of the carrier amplifier and the peaking amplifier is RL, and the load impedance at a combining point (output terminal) is RL/2. On the other hand, when the peaking amplifier is turned off (left diagram in the upper part), the load impedance seen from the carrier amplifier is 2RL because of the phase shifter that functions as an impedance inverter.

In general, the efficiency of the amplifier tends to increase as the load impedance increases. Therefore, as illustrated in the graph in the lower part, compared with the case of the Class AB amplifier that is capable of outputting the same peak power, in a region AR1 where the peaking amplifier is off, the use of the Doherty amplifier can improve the efficiency by increasing the load impedance. Furthermore, in a region AR2 where the peaking amplifier is on, the use of the Doherty amplifier can improve the efficiency by utilizing parallel operation of the carrier amplifier and the peaking amplifier.

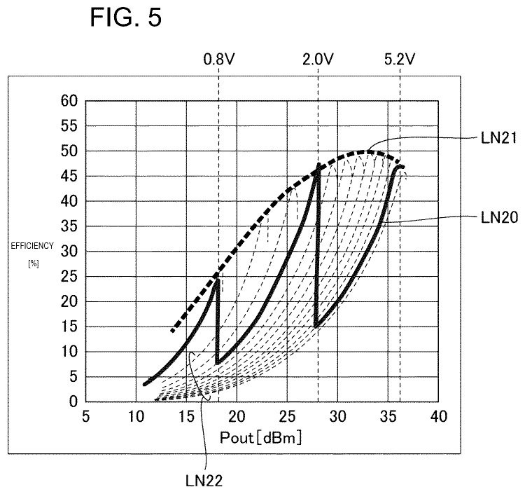

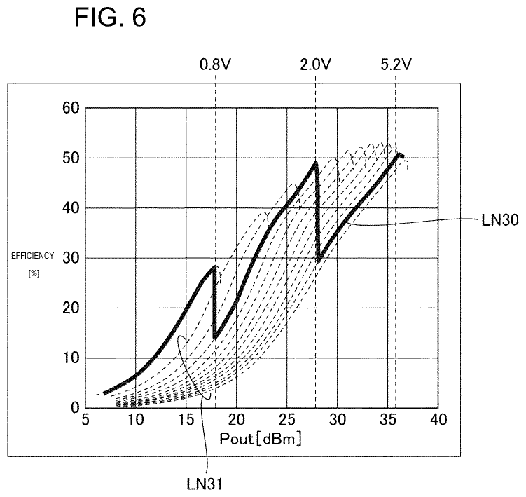

Next, referring to FIG. 5 and FIG. 6, the efficiency is described in relation to the output power for the cases of the respective envelope tracking modes illustrated in FIG. 3 and for the cases where the Doherty amplifier is used.

In FIG. 5, a solid line LN20 indicates the efficiency in the case of the digital ET mode. A dashed line LN21 indicates the efficiency in the case of the analog ET mode. A group of graphs indicated by dashed lines LN22 indicates the efficiencies in the APT mode for the Class AB amplifier that are associated with the different power supply voltages VCC.

In the APT mode (dashed line LN22), once the power supply voltage VCC is determined, the efficiency changes along with the graph that is associated with this power supply voltage VCC. As the power supply voltage VCC increases, the efficiency changes along with the graph that has a peak position closer to the high output side. Therefore, a high efficiency is achieved when the output power associated with the power supply voltage VCC is used. However, the efficiency decreases when the output power varies.

In the analog ET mode (dashed line LN21), the graph corresponds to the one formed by linking the peaks of the respective graphs of the APT mode. The graph shows high efficiency over the entire range of the output power. However, in order to achieve this, it is necessary to change, depending on the output power, the power supply voltage VCC continuously.

In the digital ET mode (solid line LN20) having a plurality of voltage levels, the voltage level of the power supply voltage VCC is switched depending on the output power. That is to say, the graph corresponds to the one formed by combining some of the graphs of the APT mode. In the case of the example of FIG. 5, the power supply voltage VCC is switched in three stages of 0.8 V, 2.0 V, and 5.2 V. Therefore, the efficiency changes along with the graph for a power supply voltage VCC of 5.2 V when the output power is greater than or equal to 27 dBm, and the efficiency changes along with the graph for a power supply voltage VCC of 2.0 V when the output power is 18 dBm to 27 dBm. Furthermore, the efficiency changes along with the graph for a power supply voltage VCC of 0.8 V when the output power is less than 10 dBm. Therefore, the digital ET mode has no constraint like the ones in the analog ET mode and has an improved efficiency compared with the APT mode.

FIG. 6 is a diagram illustrating the efficiency in the case where the Doherty amplifier is used. A solid line LN30 indicates the case of the digital ET mode, and each of a group of graphs indicated by dashed lines LN31 illustrates the efficiency in the APT mode, which is associated with each power supply voltage VCC of the Doherty amplifier.

In the case where the Doherty amplifier is used, as illustrated in FIG. 4, by turning the peaking amplifier off in the low output region, the efficiency is improved in each power supply voltage VCC compared with the case of FIG. 5 even in the case of the APT mode (dashed line LN31). Therefore, the efficiency is further improved (solid line LN30) by operating in the digital ET mode.

### (Characteristics of Power Conversion Circuit)

A typical Doherty amplifier includes one carrier amplifier and one peaking amplifier. Therefore, the back-off amount caused by switching the peaking amplifier is 6 dB. On the other hand, in the case where a multilevel modulation control with a large quantity of symbols such as 16-Quadrature Amplitude Modulation (QAM), 64-QAM, 256-QAM, or the like is used, the quantity of the symbols having smaller amplitudes increases. Thus, the overall average power decreases. This increases the difference between the peak power and the average power, and thus, a larger back-off becomes necessary.

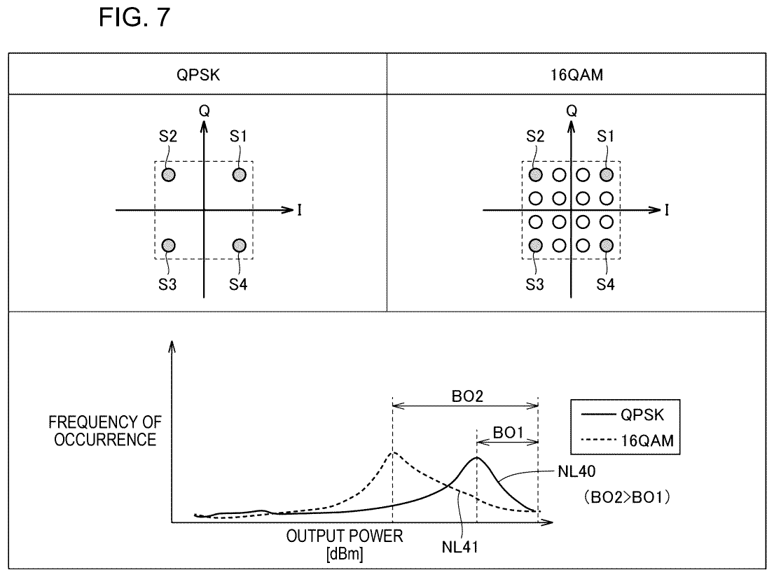

FIG. 7 is a diagram to illustrate the relationship between the modulation scheme and the back-off amount. FIG. 7 illustrates a graph (lower part) of the frequency of occurrence of the output power required for transition between symbols for the case where Quadrature Phase Shift Keying (QPSK) having four symbols is used as the modulation scheme (left diagram in the upper part) and for the case where 16-QAM having 16 symbols is used as the modulation scheme (right diagram in the upper part). In the graph in the lower part, a solid line LN40 indicates the case of QPSK, and a dashed line LN41 indicates the case of 16-QAM.

In the case of QPSK, one symbol is positioned in each quadrant, and the total of four symbols S1 to S4 are arranged on the constellation, and in the case of 16-QAM, four symbols are positioned in each quadrant, and the total of 16 symbols are arranged on the constellation. In the case of 16-QAM, the probability of transition between symbols is higher for the symbols in an inner region than the symbols S1 to S4. Thus, as illustrated in the graph in the lower part, the output power at which the frequency of occurrence becomes the highest (that is, average power) is lower than that of the case of QPSK. Therefore, a back-off amount BO2 in the case of 16-QAM is greater than a back-off amount BO1 in the case of QPSK (BO2>BO1).

As described above, the required back-off amount is different depending on the modulation scheme. Thus, when the multilevel modulation control is performed or when the transmission is performed by switching the modulation scheme, there is a risk that a usual Doherty amplifier including one carrier amplifier and one peaking amplifier will not be able to set an appropriate back-off amount for the modulation scheme and the overall efficiency of the amplifier will decrease.

In view of this, the power amplifying circuit 100 of Embodiment 1 is configured so as to enable the setting of the back-off amount in a variable manner by configuring at least one of the carrier amplifier and the peaking amplifier to have a plurality of amplifiers connected in parallel to each other and by changing, depending on the input signal, the quantity of amplifiers to use. According to the configuration described above, it becomes possible to set an appropriate back-off amount for the input signal, and thus, it becomes possible to reduce the decrease in efficiency of the amplifier.

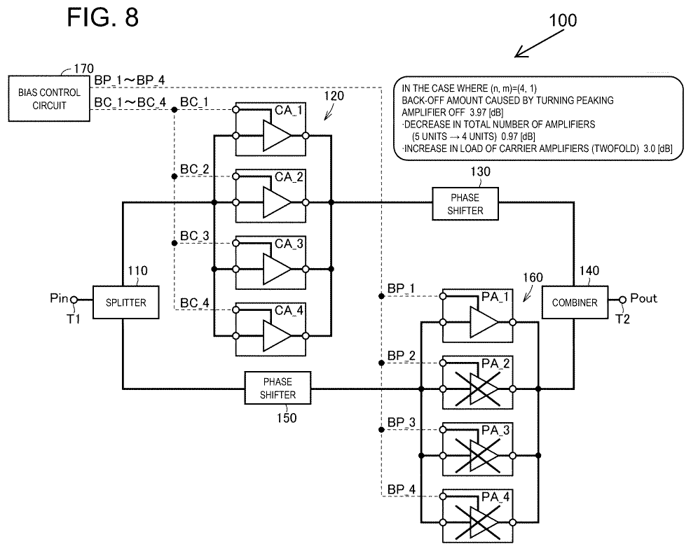

Next, referring to FIG. 8 to FIG. 11, examples of the back-off amount are described for the cases where the numbers of amplifiers included in the carrier amplifier group 120 and the peaking amplifier group 160 are changed. In the examples of FIG. 8 to FIG. 11, the examples are illustrated for the case where each of the carrier amplifier group 120 and the peaking amplifier group 160 includes four amplifiers.

(1) In the Case Where n=m

In the case where the numbers of activated amplifiers in the carrier amplifier group 120 and the peaking amplifier group 160 are the same, as is the case of a typical Doherty amplifier, the back-off amount is 6 dB because the total quantity of the amplifiers decreases by half when the peaking amplifiers are turned off.

(2) In the Case Where n>m

In the case where the quantity of activated amplifiers in the carrier amplifier group 120 is greater than the quantity of activated amplifiers in the peaking amplifier group 160, the total quantity of the amplifiers is greater than the half when the peaking amplifiers are turned off. Therefore, the back-off amount caused by decreasing the quantity of amplifiers is smaller than 3 dB, and thus, the total back-off amount is smaller than 6 dB.

FIG. 8 is a diagram illustrating an exemplary operation in the case where the quantity of the carrier amplifiers is four and the quantity of the peaking amplifiers is one (n=4 and m=1). In this case, when the peaking amplifier is on, the total quantity of the amplifiers is five, and when the peaking amplifier is off, the total quantity of the amplifiers is four. Therefore, in this case, the back-off amount caused by decreasing the quantity of amplifiers is 0.97 dB. Therefore, the total back-off amount including a back-off amount of 3.0 dB caused by increasing the load of the carrier amplifiers is about 4 dB (3.97 dB).

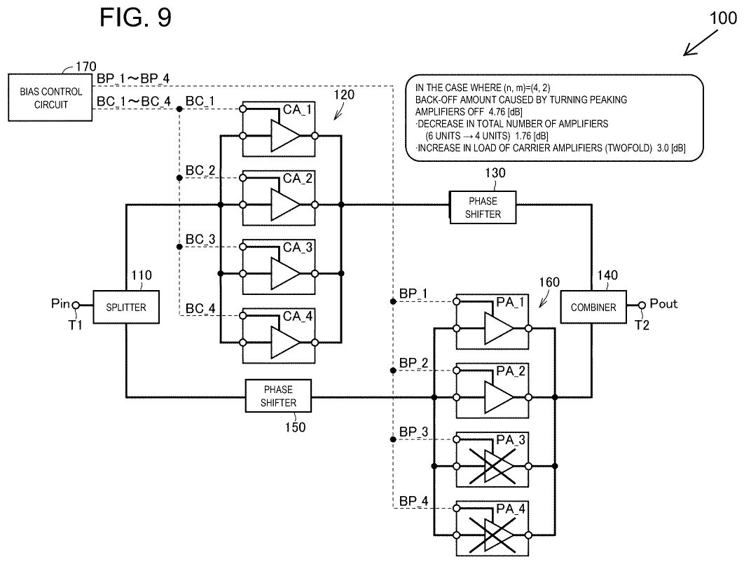

Further, FIG. 9 is a diagram illustrating an exemplary operation in the case where the quantity of the carrier amplifiers is four and the quantity of the peaking amplifiers is two (n=4 and m=2). In this case, the quantity of amplifiers decreases from six to four when the peaking amplifiers are turned off, and thus, the back-off amount is 1.76 dB. Therefore, the total back-off amount is about 5 dB (4.76 dB).

(3) In the Case Where n>m

In the case where the quantity of activated amplifiers in the peaking amplifier group 160 is greater than the quantity of activated amplifiers in the carrier amplifier group 120, the total quantity of the amplifiers is less than the half when the peaking amplifiers are turned off.

Therefore, the back-off amount caused by decreasing the quantity of amplifiers is greater than 3 dB, and thus, the total back-off amount is greater than 6 dB.

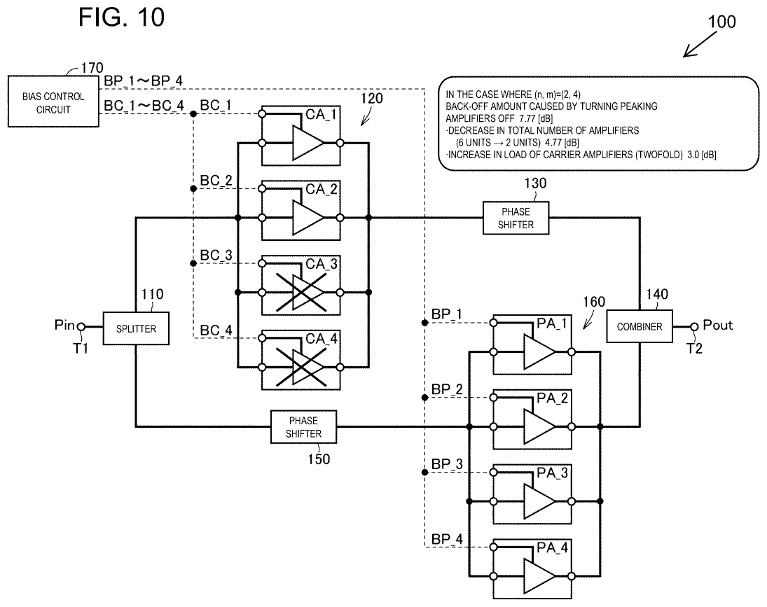

FIG. 10 is a diagram illustrating an exemplary operation in the case where the quantity of the carrier amplifiers is two and the quantity of the peaking amplifiers is four (n=2 and m=4). In this case, when the peaking amplifiers are on, the total quantity of the amplifiers is six, and when the peaking amplifiers are off, the total quantity of the amplifiers is two. Therefore, in this case, the back-off amount caused by decreasing the quantity of amplifiers is 4.77 dB. Therefore, the total back-off amount including a back-off amount of 3.0 dB caused by increasing the load of the carrier amplifiers is about 8 dB (7.77 dB).

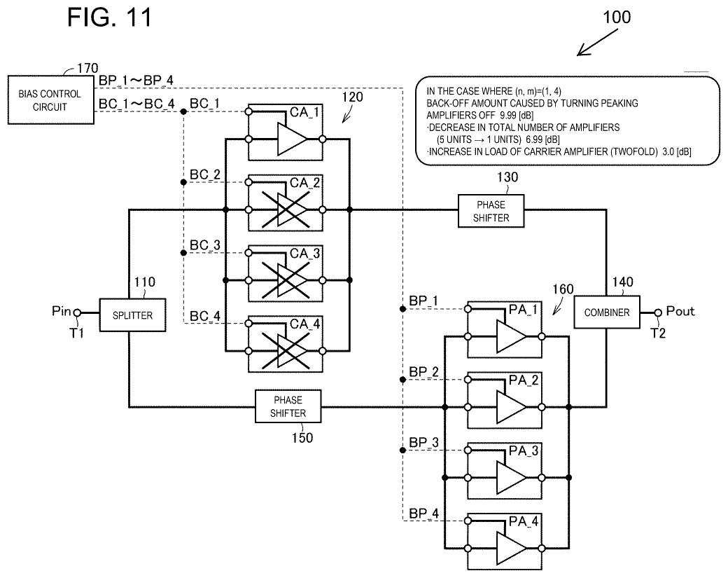

Further, FIG. 11 is a diagram illustrating an exemplary operation in the case where the quantity of the carrier amplifiers is one and the quantity of the peaking amplifiers is four (n=1 and m=4). In this case, the quantity of amplifiers decreases from five to one when the peaking amplifiers are turned off, and thus, the back-off amount is 6.99 dB. Therefore, the total back-off amount is about 10 dB (9.99 dB).

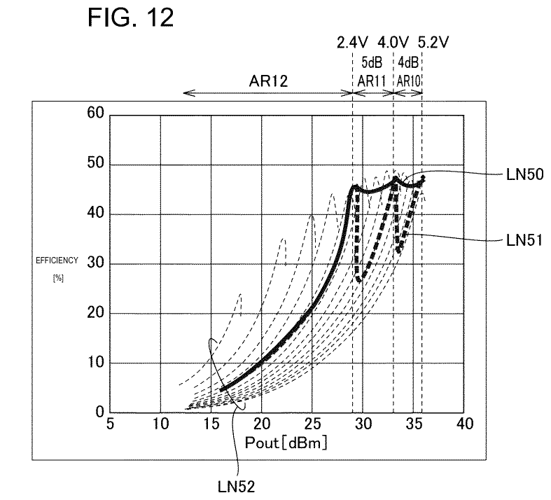

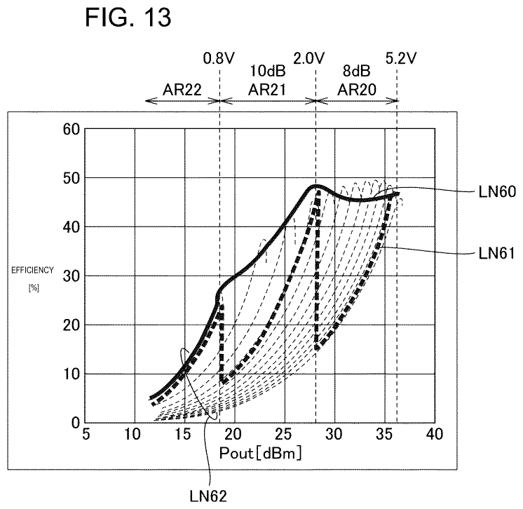

FIG. 12 and FIG. 13 are diagrams illustrating the efficiency in relation to the output power in the power amplifying circuit in which the controls of changing the quantity of amplifiers described in the foregoing (2) and (3) are employed in combination with the digital ET mode. FIG. 12 is the example of the case where n>m described in (2), and FIG. 13 is the example of the case where n<m described in (3). In FIG. 12 and FIG. 13, the efficiency in the case of Embodiment 1 is indicated by solid lines LN50 and LN60, respectively. A dashed line LN5 indicates the efficiency in the case where n=m, and a group of graphs indicated by dashed lines LN52 indicates the efficiencies of the carrier amplifier in the APT mode that are associated with the different power supply voltages VCC.

FIG. 12 illustrates an application example of the case of the foregoing (2), in which the power supply voltage VCC is switched at 2.4 V, 4.0 V, and 5.2 V. In a region AR10 where the output power is 33 dBm to 37 dBm, the power supply voltage VCC is set at 5.2 V. Furthermore, the quantity of the carrier amplifiers is set to four, and the quantity of the peaking amplifiers is set to one, which is (n, m)=(4, 1). In this case, as illustrated in FIG. 8, the back-off amount is about 4 dB.

At the time point where the peaking amplifier whose output power is 33 dBm is turned off, the power supply voltage VCC is switched to 4.0 V. Furthermore, the quantity of the carrier amplifiers is set to four, and the quantity of the peaking amplifiers is set to two, which is (n, m)=(4, 2). In this case, as illustrated in FIG. 9, the back-off amount is about 5 dB (region AR11).

Further, at the time point where the peaking amplifier whose output power is 28 dBm is turned off, the power supply voltage VCC is switched to 2.4 V. Furthermore, the quantity of the carrier amplifiers is set to four, and the quantity of the peaking amplifiers is set to zero, which is (n, m)=(4, 0). In a region AR12 where the output power is less than or equal to 28 dBm, the operation is performed in the APT mode only with the carrier amplifiers. As described above, by appropriately changing the power supply voltage and the quantity of amplifiers, as indicated by the solid line LN50, particularly in the regions AR10 and AR11, it becomes possible to improve the efficiency closer to that of the case of the analog ET mode without switching the power supply voltage at high frequency.

FIG. 13 illustrates an application example of the case of the foregoing (3), in which the power supply voltage VCC is switched at 0.8 V, 2.0 V, and 5.2 V. In a region AR20 where the output power is 28 dBm to 36 dBm, the power supply voltage VCC is set at 5.2 V. Furthermore, the quantity of the carrier amplifiers is set to two, and the quantity of the peaking amplifiers is set to four, which is (n, m)=(2, 4). In this case, as illustrated in FIG. 10, the back-off amount is about 8 dB.

At the time point where the peaking amplifier whose output power is 28 dBm is turned off, the power supply voltage VCC is switched to 2.0 V. Furthermore, the quantity of the carrier amplifiers is set to one, and the quantity of the peaking amplifiers is set to four, which is (n, m)=(1, 4). In this case, as illustrated in FIG. 9, the back-off amount is about 10 dB (region AR21).

Further, at the time point where the peaking amplifier whose output power is 18 dBm is turned off, the power supply voltage VCC is switched to 0.8 V. Furthermore, the quantity of the carrier amplifiers is set to four, and the quantity of the peaking amplifiers is set to zero, which is (n, m)=(4, 0). In a region AR22 where the output power is less than or equal to 18 dBm, the operation is performed in the APT mode only with the carrier amplifiers. As described above, by appropriately changing the power supply voltage and the quantity of amplifiers, as indicated by the solid line LN60, particularly in the regions AR20 and AR21, it becomes possible to improve the efficiency closer to that of the case of the analog ET mode without switching the power supply voltage at high frequency.

As described above, it becomes possible to improve the efficiency of the power amplifying circuit while securing a desired back-off amount by configuring the power amplifying circuit using the Doherty amplifier in which the carrier amplifier group and/or the peaking amplifier group 160 includes a plurality of amplifiers and by operating the power amplifying circuit in the digital ET mode while changing the quantity of amplifiers to use on the basis of the input signal.

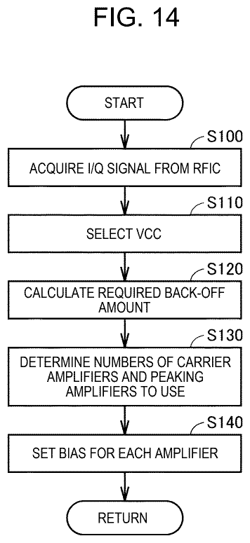

FIG. 14 is a flowchart illustrating the control to be performed in the communication device 10. Each step illustrated in FIG. 14 is performed by the bias control circuit 170 of the power amplifying circuit 100 or the envelope tracker 230 of the power supply circuit 200.

Referring to FIG. 14, in step (hereinafter, abbreviated as “S”) 100, the envelope tracker 230 acquires the I/Q signal of the input signal from the RFIC 300. Next, in S110, the envelope tracker 230 calculates the magnitude of the input signal on the basis of the acquired I/Q signal and selects the power supply voltage VCC that is associated with this input signal.

In S120, on the basis of the selection signal SEL from the envelope tracker 230, the bias control circuit 170 calculates a required back-off amount for the selected power supply voltage VCC. Here, the required back-off amount is appropriately determined by the specification of the communication device 10 in which this power amplifying circuit 100 is employed. For example, a plurality of maps each illustrating the efficiencies such as the one illustrated in FIG. 12 or FIG. 13 is stored in advance in a memory device (not illustrated) included in the power amplifying circuit 100, and on the basis of the selected power supply voltage and other information, the corresponding table is selected from a plurality of stored lookup tables.

Subsequently, in S130, on the basis of the information of the selected map, the bias control circuit 170 determines the quantity of the carrier amplifiers and the quantity of the peaking amplifiers to use. Then, the bias control circuit 170 sets the bias voltage for each amplifier in such a way that the determined quantity of amplifiers are activated.

By performing the control by following the processes described above, it becomes possible to reduce the decrease in efficiency of the power amplifier even in the case where the required back-off amount varies.

The “carrier amplifier group 120” and the “peaking amplifier group 160” in Embodiment 1 correspond to a “first amplifier group” and a “second amplifier group” in the present disclosure, respectively. The “phase shifter 130” and the “phase shifter 150” in Embodiment 1 correspond to a “first phase shifter” and a “second phase shifter” in the present disclosure, respectively. The “bias control circuit 170” in Embodiment 1 corresponds to a “control circuit” in the present disclosure.

### Embodiment 2

In Embodiment 2, there is described a configuration that stabilizes characteristics of a power amplifier by changing the quantity of amplifiers to use in each amplifier group on the basis of the variation in the load impedance of the power amplifier.

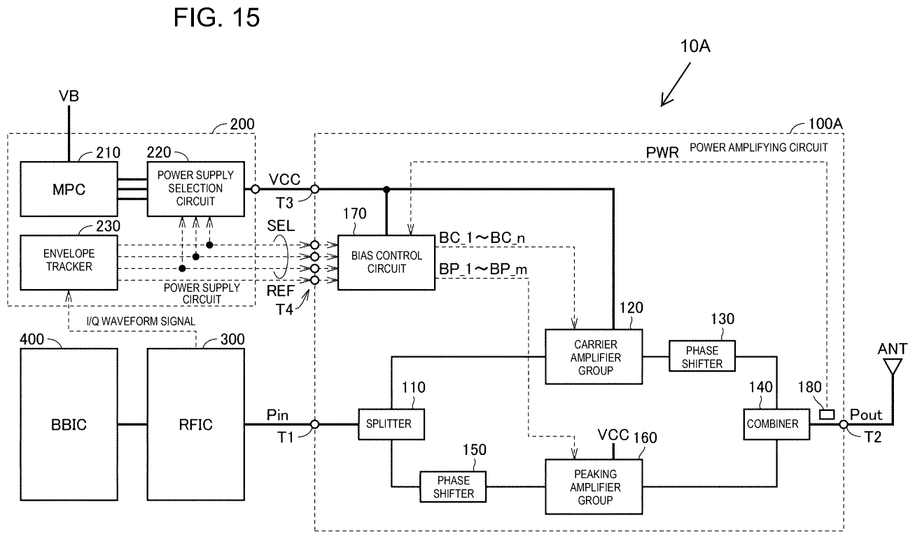

FIG. 15 is a schematic configuration diagram of a communication device 10A in which a power amplifying circuit 100A according to Embodiment 2 is employed. In the communication device 10A, the power amplifying circuit 100 of the communication device 10, which is described using FIG. 1 of Embodiment 1, is replaced with the power amplifying circuit 100A. More specifically, the power amplifying circuit 100A has a configuration in which a detector 180 for detecting output power outputted from the output terminal T2 is further included in addition to the configuration of the power amplifying circuit 100. In FIG. 15, the descriptions regarding constituent elements overlapping with those of FIG. 1 are not repeated.

Referring to FIG. 15, the detector 180 includes a coupler that includes, for example, a line arranged in parallel to a transmission path from the combiner 140 to the output terminal T2. The detector 180 detects the magnitude of the output power on the basis of a signal induced in this line by the output signal outputted from the output terminal T2. A detected value of the detector 180 is rectified into a DC signal, and the rectified DC signal is outputted to the bias control circuit 170.

The bias control circuit 170 detects a variation in the load impedance of the antenna ANT by comparing a detected value of the output power detected by the detector 180 and a command value of the output power calculated from the input signal. Specifically, the bias control circuit 170 determines that there is a decrease in the load impedance when the detected value is greater than the command value and that there is an increase in the load impedance when the detected value is smaller than the command value. Furthermore, the bias control circuit 170 changes the numbers of amplifiers to use in the carrier amplifier group 120 and the peaking amplifier group 160 by changing the bias voltage for each amplifier on the basis of the variation in the load impedance of the antenna ANT. Note that the foregoing process may be performed using the RFIC 300 or the BBIC 400, instead of using the bias control circuit 170. In that case, the detected value of the detector 180 is outputted to the RFIC 300 or the BBIC 400.

As described in Embodiment 1, in the power amplifying circuit, when the load impedance connected to the output terminal varies, the efficiency of the power converter can change accordingly. Further, not only the efficiency, but also the gain and distortion of the power amplifying circuit are affected by the variation in the load impedance. That is to say, the change of the load impedance can cause degradation of the characteristics of the power amplifying circuit.

Particularly, in the cases where high frequency signals of millimeter waves or shorter wavelengths are used, in some cases, the power amplifying circuit is directly connected to the antenna without any element such as a filter, a switch, or the like therebetween in order to reduce the decrease in loss at a transmission line. With the configuration described above, when the antenna is in contact with a human hand or a metal part, the load impedance can vary greatly.

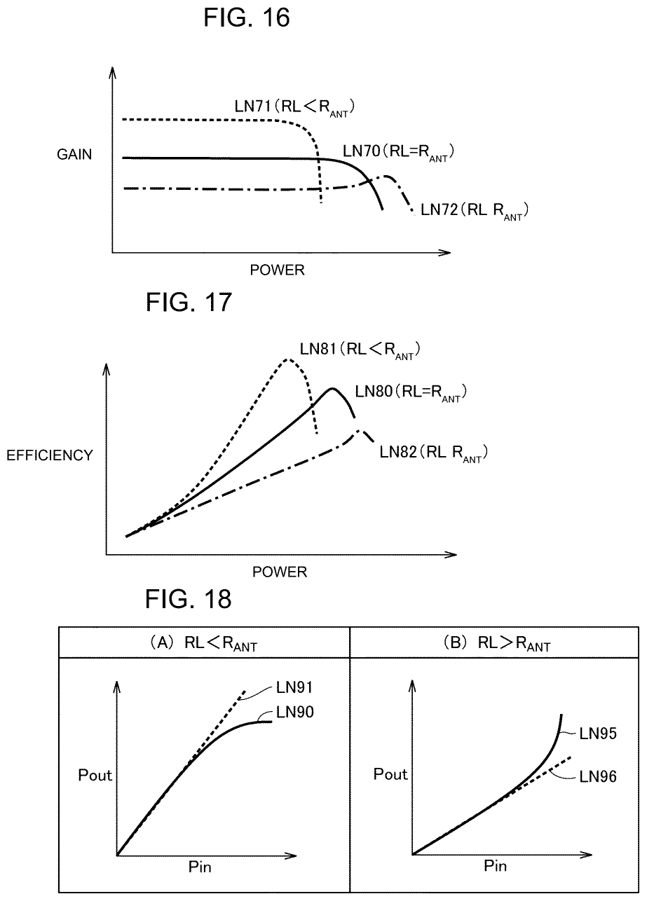

FIG. 16 to FIG. 18 are diagrams illustrating the changes in the gain, the efficiency, and the distortion of the power amplifying circuit when the load impedance of the antenna varies from the characteristic impedance (for example, 50Ω), respectively.

In FIG. 16, a solid line LN70 indicates the gain characteristic in the case where the load impedance of the antenna (R_{ANT}) coincides with the characteristic impedance (RL) (RL=R_{ANT}), and a dashed line LN71 indicates the gain characteristic in the case where the load impedance increases above the characteristic impedance (RL<R_{ANT}). Further, a dashed-dotted line LN72 indicates the gain characteristic in the case where the load impedance decreases below the characteristic impedance (RL>R_{ANT}).

In the case where the load impedance increases (dashed line LN71), the gain increases on the low output side. However, the gain decreases sharply on the high output side, and a desired power cannot be outputted. On the other hand, in the case where the load impedance decreases (dashed-dotted line LN72), the power can be outputted up to the high output side. However, the gain is lower over the entire range, compared with the case of the characteristic impedance.

In FIG. 17, a solid line LN80 indicates the efficiency of the power amplifying circuit in the case where the load impedance of the antenna (R_{ANT}) coincides with the characteristic impedance (RL) (RL=R_{ANT}), and a dashed line LN71 indicates the efficiency in the case where the load impedance increases above the characteristic impedance (RL<R_{ANT}). Further, a dashed-dotted line LN72 indicates the efficiency in the case where the load impedance decreases below the characteristic impedance (RL>R_{ANT}).

When the load impedance increases (dashed line LN81), the efficiency increases, but the peak of the efficiency moves toward the low output side. Furthermore, on the high output side, the efficiency decreases compared with the case of the characteristic impedance. On the other hand, when the load impedance decreases (dashed-dotted line LN82), the efficiency is lower over the entire range.

In FIG. 18, the left diagram (A) illustrates the output signal in relation to the input signal in the case where the load impedance of the antenna increases above the characteristic impedance (RL<R_{ANT}) (solid line LN90), and the right diagram (B) illustrates the output signal in relation to the input signal in the case where the load impedance of the antenna decreases below the characteristic impedance (RL>R_{ANT}) (solid line LN95). In these two graphs of FIG. 18, dashed lines LN91 and LN96 each indicate the case where the load impedance coincides with the characteristic impedance (RL=R_{ANT}). As illustrated in FIG. 18, the distortion is formed on the high output side in both the cases where the load impedance increases and decreases.

In the power amplifying circuit 100A of Embodiment 2, the variation in the load impedance is calculated from the variation in the output power detected by the detector 180, and on the basis of that, the numbers of amplifiers to use in the carrier amplifier group 120 and the peaking amplifier group 160 are changed. More specifically, when the load impedance of the antenna ANT varies, the quantity of amplifiers is adjusted in such a way that the load impedance of each amplifier in the carrier amplifier group 120 and the peaking amplifier group 160 remains equal to the load impedance prior to the change. By doing this, in the power amplifying circuit 100A, the operation becomes the same as in the case where the load impedance of each amplifier coincides with that of the case of the characteristic impedance, and thus, even when the load impedance of the antenna ANT varies, the characteristics of the power amplifying circuit can be maintained.

### (1) In the Case Where Load Impedance Increases

Consider the case where n carrier amplifiers and m peaking amplifiers are used in the power amplifying circuit 100A. In the case where the load impedance of the antenna ANT is the characteristic impedance RL, at the input terminals of the combiner 140, both the load impedances of the path of the carrier amplifier group 120 and the path of the peaking amplifier group 160 are 2RL.

In this case, in the carrier amplifier group 120, n amplifiers are connected in parallel, and thus, the load impedance of each amplifier is 2nRL. Further, in the peaking amplifier group 160, m amplifiers are connected in parallel, and thus, the load impedance of each amplifier is 2mRL.

In this case, when the load impedance of the antenna ANT varies and becomes twice (2RL) the characteristic impedance RL, at the input terminals of the combiner 140, both the load impedances of the path of the carrier amplifier group 120 and the path of the peaking amplifier group 160 change to 4RL. This increases the load impedance of each amplifier in the peaking amplifier group 160 to 4mRL.

On the other hand, in the carrier amplifier group 120, because of the phase shifter 130 that serves as an impedance inverter, the load impedance at the output port of the carrier amplifier group 120 is RL. Therefore, the load impedance of each amplifier in the carrier amplifier group 120 decreases to nRL.

Therefore, with regard to the carrier amplifier group 120, the quantity of amplifiers is doubled, and with regard to the peaking amplifier group 160, the quantity of amplifiers is reduced to half. In this way, the load impedance per amplifier for the carrier amplifier group 120 is 2nRL, and the load impedance per amplifier for the peaking amplifier group 160 is 2mRL. This makes the load impedance of each amplifier equal to the load impedance of the case of the characteristic impedance. Accordingly, even when the load impedance of the antenna ANT varies, it becomes possible to maintain the characteristics of the power amplifying circuit 100A.

### (2) In the Case Where Load Impedance Decreases

In the case where the load impedance of the antenna ANT changes to one-half (½) of the characteristic impedance RL (RL/2), at the input terminals of the combiner 140, both the load impedances of the path of the carrier amplifier group 120 and the path of the peaking amplifier group 160 are RL.

With regard to the peaking amplifier group 160, m amplifiers are connected in parallel, and thus, the load impedance of each amplifier decreases from 2mRL to mRL. On the other hand, with regard to the carrier amplifier group 120, because of the phase shifter 130, the load impedance at the output port of the carrier amplifier group 120 is 4RL. Furthermore, because n amplifiers are connected in parallel, the load impedance per amplifier increases from 2nRL to 4nRL.

Therefore, with regard to the carrier amplifier group 120, the quantity of amplifiers is reduced to half, and with regard to the peaking amplifier group 160, the quantity of amplifiers is doubled. In this way, the load impedance per amplifier for the carrier amplifier group 120 is 2nRL, and the load impedance per amplifier for the peaking amplifier group 160 is 2mRL. This makes the load impedance of each amplifier equal to the load impedance of the case of the characteristic impedance. Accordingly, even when the load impedance of the antenna ANT varies, it becomes possible to maintain the characteristics of the power amplifying circuit 100A.

As described above, it becomes possible to stabilize the characteristics of the power increasing circuit irrespective of the variation in load by monitoring the load of the power amplifying circuit, increasing the quantity of the carrier amplifiers while decreasing the quantity of the peaking amplifiers when the load increases, and decreasing the quantity of the carrier amplifiers while increasing the quantity of the peaking amplifiers when the load decreases.

Note that depending on the quantity of amplifiers included in the carrier amplifier group 120 and the peaking amplifier group 160, changing the quantity of amplifiers may result in a shortage or a non-integer value for the quantity of amplifiers after the change. In such cases, by selecting the amplifiers whose quantity is the closest to the calculation result, the degree of degradation in the characteristics can be decreased.

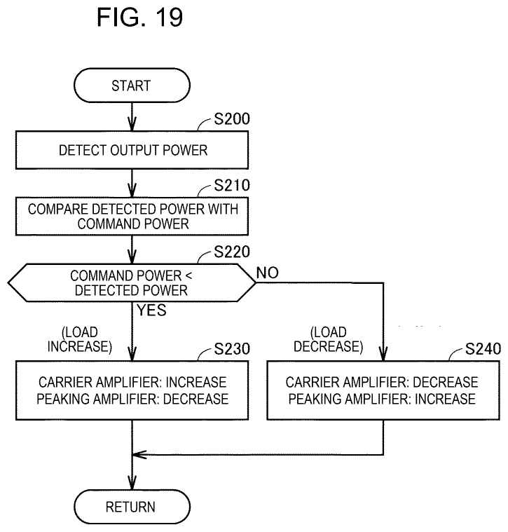

FIG. 19 is a flowchart illustrating control to be performed in a communication device 10 of Embodiment 2. Referring to FIG. 19, in S200, the bias control circuit 170 calculates output power on the basis of a detected value detected by the detector 180. Further, in S210, the bias control circuit 170 compares a detected power detected by the detector 180 with a command power calculated from the input signal.

When the detected power is greater than the command power (YES in S220), the bias control circuit 170 determines that there is an increase in the load impedance of the antenna ANT, and the process proceeds to S230 where the quantity of the carrier amplifiers is increased, and the quantity of the peaking amplifiers is decreased. On the other hand, when the detected power is less than or equal to the command power (NO in S220), the bias control circuit 170 determines that there is a decrease in the load impedance of the antenna ANT, and the process proceeds to S240 where the quantity of the carrier amplifiers is decreased, and the quantity of the peaking amplifiers is increased.

According to the control performed by following the process described above, it becomes possible to maintain the characteristics of the power increasing circuit even when the load of antenna varies.

### (Aspect)

It will be appreciated by those skilled in the art that a plurality of exemplary embodiments described above are specific examples of the following aspects.

(First Item) A power amplifying circuit according to one aspect includes an input terminal, an output terminal, a splitter connected to the input terminal, a combiner connected to the output terminal, a first amplifier group, a second amplifier group, a first phase shifter, and a control circuit. The splitter splits an input signal from the input terminal for two paths. The first amplifier group is connected to one of the two paths of the splitter. The first phase shifter is connected between the first amplifier group and the combiner. The second amplifier group is connected between another of the two paths of the splitter and the combiner. The control circuit supplies bias signals to the first amplifier group and the second amplifier group. Each of the first amplifier group and the second amplifier group includes at least one amplifier. At least one of the first amplifier group and the second amplifier group includes a plurality of amplifiers. The control circuit changes a quantity of amplifiers to use in each of the first amplifier group and the second amplifier group by adjusting a level of the bias signal being supplied to each amplifier.

(Second Item) In the power amplifying circuit according to the first item, the control circuit changes the quantity of amplifiers to use by adjusting, depending on a magnitude of the input signal, the level of the bias signal being supplied to each amplifier.

(Third Item) In the power amplifying circuit according to the second item, the control circuit increases a total quantity of amplifiers to use as the magnitude of the input signal increases.

(Fourth Item) In the power amplifying circuit according to the second item or the third item, a power supply voltage is supplied to the first amplifier group and the second amplifier group, the power supply voltage being set at a plurality of levels depending on the magnitude of the input signal.

(Fifth Item) In the power amplifying circuit according to the fourth item, the control circuit changes the quantity of amplifiers to use by adjusting, depending on a back-off amount associated with the level of the power supply voltage being supplied, the level of the bias signal being supplied to each amplifier.

(Sixth Item) In the power amplifying circuit according to the fifth item, in a case where the back-off amount is 6 dB, the control circuit sets the quantity of amplifiers to use in the first amplifier group equal to the quantity of amplifiers to use in the second amplifier group.

(Seventh Item) In the power amplifying circuit according to the fifth item or the sixth item, in a case where the back-off amount is less than 6 dB, the control circuit sets the quantity of amplifiers to use in the first amplifier group greater than the quantity of amplifiers to use in the second amplifier group.

(Eighth Item) In the power amplifying circuit according to any one of the fifth item to the seventh item, in a case where the back-off amount is greater than 6 dB, the control circuit sets the quantity of amplifiers to use in the second amplifier group greater than the quantity of amplifiers to use in the first amplifier group.

(Ninth Item) In the power amplifying circuit according to any one of the first item to the eighth item, the power amplifying circuit is a Doherty amplifier. The first amplifier group includes a carrier amplifier. The second amplifier group includes a peaking amplifier.

(Tenth Item) In the power amplifying circuit according to any one of the first item to the ninth item, each amplifier included in the first amplifier group is a Class A amplifier or a Class AB amplifier. Each amplifier included in the second amplifier group is a Class C amplifier.

(Eleventh Item) In the power amplifying circuit according to any one of the first item to the tenth item, a digital envelope tracking mode is employed for the first amplifier group and the second amplifier group.

(Twelfth Item) In the power amplifying circuit according to any one of the first item to the eleventh item, the first phase shifter is a quarter-wavelength transmission line.

(Thirteenth Item) In the power amplifying circuit according to any one of the first item to the twelfth item, a second phase shifter connected between the splitter and the second amplifier group is further included.

(Fourteenth Item) The power amplifying circuit according to any one of the first item to the thirteenth item further includes a detector that detects a magnitude of an output signal outputted from the output terminal. The control circuit changes the quantity of amplifiers to use by adjusting the level of the bias signal being supplied to each amplifier on a basis of a difference or a ratio between the input signal and the output signal.

(Fifteenth Item) The power amplifying circuit according to the fourteenth item, in a case where a load of the power amplifying circuit increases, the control circuit increases the quantity of amplifiers to use in the first amplifier group and decreases the quantity of amplifiers to use in the second amplifier group.

(Sixteenth Item) The power amplifying circuit according to the fourteenth item or the fifteenth item, in a case where a load of the power amplifying circuit decreases, the control circuit decreases the quantity of amplifiers to use in the first amplifier group and increases the quantity of amplifiers to use in the second amplifier group.

(Seventeenth Item) A control method of a power amplifying circuit according to one aspect relates to a control method for a power amplifying circuit including an input terminal, an output terminal, a first amplifier group, and a second amplifier group, the first amplifier group and the second amplifier group being connected in parallel between the input terminal and the output terminal. At least one of the first amplifier group and the second amplifier group includes a plurality of amplifiers. The control method includes: (i) a step of acquiring a magnitude of an input signal; (ii) a step of selecting a back-off amount that is associated with the magnitude of the input signal acquired; and (iii) a step of setting a quantity of amplifiers to use in each of the first amplifier group and the second amplifier group on a basis of the input signal and the back-off amount.

(Eighteenth Item) A control method of a power amplifying circuit according to one aspect relates to a control method for a power amplifying circuit including an input terminal, an output terminal, a first amplifier group, and a second amplifier group, the first amplifier group and the second amplifier group being connected in parallel between the input terminal and the output terminal. At least one of the first amplifier group and the second amplifier group includes a plurality of amplifiers. The control method includes: (i) a step of acquiring a magnitude of an input signal; (ii) a step of acquiring a magnitude of an output signal; and (iii) a step of changing a quantity of amplifiers to use in each of the first amplifier group and the second amplifier group on a basis of the input signal and the output signal.

It is to be understood that the embodiments disclosed herein are exemplary in all aspects and are not restrictive. It is intended that the scope of the present disclosure is defined by the claims, not by the description of the foregoing embodiments, and includes all variations which come within the meaning and range of equivalency of the claims.
10, 10A communication device
100, 100A power amplifying circuit
110 splitter
120 carrier amplifier group
130, 150 phase shifter
140 combiner
160 peaking amplifier group
170 bias control circuit
180 detector
200 power supply circuit
220 power supply selection circuit
230 envelope tracker
300 RFIC
400 BBIC
ANT antenna
BC, BP bias voltage
CA, PA amplifier
S1 to S4 symbol
T1 input terminal
T2 output terminal
T3 power supply terminal
T4 control terminal
VB battery voltage

The invention claimed is:

1. A power amplifying circuit comprising:
an input terminal and an output terminal;
a splitter connected to the input terminal and that splits an input signal from the input terminal into two paths;
a combiner connected to the output terminal;
a first amplifier group connected to a first path of the two paths of the splitter;
a first phase shifter connected between the first amplifier group and the combiner;
a second amplifier group connected between a second path of the two paths of the splitter and the combiner; and
a control circuit that supplies bias signals to the first amplifier group and the second amplifier group, wherein
at least one of the first amplifier group or the second amplifier group includes a plurality of amplifiers, and
the control circuit changes a quantity of amplifiers to use in each of the first amplifier group and the second amplifier group by adjusting a level of the bias signal being supplied to each amplifier.

2. The power amplifying circuit according to claim 1, wherein
the control circuit changes the quantity of amplifiers to use by adjusting, depending on a magnitude of the input signal, the level of the bias signal being supplied to each amplifier.

3. The power amplifying circuit according to claim 2, wherein
the control circuit increases a total quantity of amplifiers to use as the magnitude of the input signal increases.

4. The power amplifying circuit according to claim 2, wherein
a power supply voltage is supplied to the first amplifier group and the second amplifier group, the power supply voltage being set at a plurality of levels depending on the magnitude of the input signal.

5. The power amplifying circuit according to claim 4, wherein
the control circuit changes the quantity of amplifiers to use by adjusting, depending on a back-off amount associated with the level of the power supply voltage being supplied, the level of the bias signal being supplied to each amplifier.

6. The power amplifying circuit according to claim 5, wherein
in a case where the back-off amount is 6 dB, the control circuit sets a first quantity of amplifiers to use in the first amplifier group equal to a second quantity of amplifiers to use in the second amplifier group.

7. The power amplifying circuit according to claim 5, wherein
in a case where the back-off amount is less than 6 dB, the control circuit sets a first quantity of amplifiers to use in the first amplifier group greater than a second quantity of amplifiers to use in the second amplifier group.

8. The power amplifying circuit according to claim 5, wherein
in a case where the back-off amount is greater than 6 dB, the control circuit sets a second quantity of amplifiers to use in the second amplifier group greater than a first quantity of amplifiers to use in the first amplifier group.

9. The power amplifying circuit according to claim 1, wherein
the power amplifying circuit is a Doherty amplifier,
the first amplifier group includes a carrier amplifier, and
the second amplifier group includes a peaking amplifier.

10. The power amplifying circuit according to claim 1, wherein
each amplifier included in the first amplifier group is a Class A amplifier or a Class AB amplifier, and
each amplifier included in the second amplifier group is a Class C amplifier.

11. The power amplifying circuit according claim 1, wherein
a digital envelope tracking mode is employed for the first amplifier group and the second amplifier group.

12. The power amplifying circuit according to claim 1, wherein
the first phase shifter is a quarter-wavelength transmission line.

13. The power amplifying circuit according to claim 1, further comprising
a second phase shifter connected between the splitter and the second amplifier group.

14. The power amplifying circuit according to claim 1, further comprising
a detector that detects a magnitude of an output signal output from the output terminal, wherein
the control circuit changes the quantity of amplifiers to use by adjusting the level of the bias signal being supplied to each amplifier on a basis of a difference or a ratio between the input signal and the output signal.

15. The power amplifying circuit according to claim 14, wherein
in a case where a load of the power amplifying circuit increases, the control circuit increases a first quantity of amplifiers to use in the first amplifier group and decreases a second quantity of amplifiers to use in the second amplifier group.

16. The power amplifying circuit according to claim 14, wherein
in a case where a load of the power amplifying circuit decreases, the control circuit decreases a first quantity of amplifiers to use in the first amplifier group and increases a second quantity of amplifiers to use in the second amplifier group.

17. A control method of a power amplifying circuit including an input terminal, an output terminal, a first amplifier group, and a second amplifier group, the first amplifier group and the second amplifier group being connected in parallel between the input terminal and the output terminal, at least one of the first amplifier group and the second amplifier group including a plurality of amplifiers,
the control method comprising:
a step of acquiring a magnitude of an input signal;
a step of selecting a back-off amount that is associated with the magnitude of the input signal acquired; and
a step of setting a quantity of amplifiers to use in each of the first amplifier group and the second amplifier group on a basis of the input signal and the back-off amount.

18. A control method of a power amplifying circuit including an input terminal, an output terminal, a first amplifier group, and a second amplifier group, the first amplifier group and the second amplifier group being connected in parallel between the input terminal and the output terminal, at least one of the first amplifier group and the second amplifier group including a plurality of amplifiers,
the control method comprising:
a step of acquiring a magnitude of an input signal;
a step of acquiring a magnitude of an output signal; and
a step of changing a quantity of amplifiers to use in each of the first amplifier group and the second amplifier group on a basis of the input signal and the output signal.
